(19) United States
(12) Patent Application Publication
(10) Pub. No.: US 2001/0018245 A1
(43) Pub. Date: Aug. 30, 2001

(54) Method for manufacturing semiconductor devices

(75) Inventor: Naohiko Kimizuka, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 09/791,221

(22) Filed: Feb. 23, 2001

(30) Foreign Application Priority Data
Feb. 24, 2000 (JP) 47427/2000

(51) Int. Cl. H01L 21/8242; H01L 21/336

(52) U.S. Cl. 438/241; 438/258; 438/981

(57) ABSTRACT

The method for manufacturing semiconductor devices, according to the present invention, that include transistors for peripheral circuits to which input and output signal lines are connected and transistors for internal circuits that have lower operation voltage than that of the transistors for peripheral circuits consists of the steps of exposing a surface of a first region forming the transistors for peripheral circuits of a semiconductor substrate, forming a first gate oxide layer by oxidizing the exposed surface of the first region in an oxidizing atmospheric gas including hydrogen atoms, exposing a surface of a second region forming the transistors for internal circuits of the semiconductor substrate, and forming a second gate oxide layer by oxidizing the exposed surface of the second region in an oxidizing atmospheric gas without hydrogen atoms and subsequently by oxidizing the exposed surface in a nitrogen monoxide atmosphere.

### BACKGROUND OF THE INVENTION

1. Field of the Invention

The present invention relates to a method for manufacturing semiconductor devices and, more particularly, to a method for forming gate insulating layers of MOS FETs.

2. Description of the Prior Arts

As a result of promoting a CMOS LSI to be higher integration and performance, a MOS FET, that is one of its fundamental elements, has been made finer, so that currently MOS FET having a length of a gate electrode of 0.13 μm have been developed. In conjunction with the fineness of the MOS FET, the thickness of the gate insulating layer of a CMOS LSI has been made thin less than 2.8 nm.

An n-type semiconductor is applied to a gate electrode of the MOS FET in a CMOS LSI with the length of the gate electrode in the range of 3 μm, regardless of an n-type MOS FET and p-type MOS FET due to simplicity and convenience of the manufacturing process. A gate electrode of an n-type semiconductor has been formed in such a way that, for example, a polycrystalline silicon layer is formed immediately after a gate insulating layer has been formed and then phosphorus is diffused into the polycrystalline silicon layer.

When this process is used, the p-type MOS FET becomes an embedded channel p-type MOS FET in which the gate electrode is made an n-type semiconductor. However, there was a problem that, as a short channel effect occurred significantly in this structure, the threshold voltages fluctuated significantly with respect to variations of the lengths of gates based on the manufacturing fluctuation. This fluctuation of the threshold voltages places restrictions on the design of integrated circuit and causes the circuit operation to be unstable, thereby resulting in deterioration of the rate of non-defective products.

Consequently, in the manufacturing process of the integrated circuits that are composed of MOS FET with the gate lengths of 0.3 μm level, the problem was dealt with by setting up the threshold voltages of the p-type MOS FET relatively high.

However, in CMOS LSIs having gate electrodes with the gate length below 0.3 μm, power supply voltages are set up less than 2.5 V that were conventionally set up at 5 V or 3.3 V, so that the threshold voltages are also inevitably required to be set up at lower values as usual. Further, when the gate lengths are made smaller as the MOS FET is made finer, the power supply voltages are also required to be further lowered, so that surface channel type p-type MOS FETs have been put into practical use in which the gate electrodes are p-type semiconductors that are less prone to the short channel effect.

That is, the CMOS LSIs with a p-n gate structure in which the gate electrodes of the n-type MOS FET are an n-type semiconductor and the gate electrodes of the p-type MOS FET are a p-type semiconductor have become a mainstream. However, a problem which will be described hereinafter has occurred for developing the CMOS LSI with the p-n gate structure.

In order to make the gate electrodes of the p-type MOS FET the p-type semiconductor, boron is dispersed into the polycrystalline silicon to be subjected to a high temperature thermal treatment. The reason why boron is used in this process is that boron has a high electrical activation rate. Alternatively, there is also a reason that, as boron is applied to the ion implantation when source and drain electrodes are formed, the process is simple and convenient which introduces boron into the gate electrodes at the same time when the source and drain electrodes are formed.

However, when the thickness of the gate insulating layer was made thin to approximately 4 nm level, the diffusion of boron in the polycrystalline silicon layer of the gate in the p-type MOS FET did not stop at the gate insulating layer and diffused to the channel region of the p-type MOS FET. When the phenomenon occurs, which is referred to as a boron penetration, controllability of the threshold voltage would be changed for the worse. In addition, it is well known that a problem may arise that the reliability of the gate insulating layer might be damaged.

Accordingly, to avoid the boron penetration, a method for forming a gate insulating layer was devised that introduced nitrogen into the gate insulating layer. In this method, C. T. Liu et al., the method for introducing nitrogen into a silicon substrate before gates are oxidized by ion implantation, Symposium on VLSI Technology, p. 18, Jun. 1996, and also L. K. Han et al., the method for heating a silicon substrate in a nitrogen monoxide atmosphere after gates are oxidized, Electron Devices Letter, vol. 16, p. 319, 1995 are included.

When such means are used, nitrogen with the mole fraction of approximately 10% can be introduced into a silicon oxide layer, so that the boron penetration can be restrained effectively.

However, a new problem, which is referred to as BT (Bias Temperature) instability and will be explained hereinafter, has occurred due to the advance of making a gate insulating layer thin originating from scaling of MOS FET.

There is a conflicting demand such as a high-speed operation and low power consumption in a CMOS LSI. In order to realize this demand, the gate insulating layer is generally made thin, causing the electric field applied to the gate insulating layer to be increased more than ever. As a result, the electric field applied to the gate insulating layer in the 0.13 μm generation of the gate length has reached 6 MV/cm. A problem can be encountered that, when the CMOS LSI is operated under such a situation, the threshold voltage of the p-type MOS FET gradually changes and the current drive ability decreases. This is the phenomenon referred to as BT instability reported by S. Ogawa et al., Physical Review, vol. 51, p. 4218, 1995, and has become an element that determines a long term reliability of the CMOS LSI.

This phenomenon is such that holes generated in an inversion layer of p-type MOS FET cause the electrochemistry reaction at an interface between the gate insulating layer and silicon substrate under a high temperature situation and, as a result, produce positive fixed charges. It has been recognized that, although the BT instability is the phenomenon that occurs regardless of whether nitrogen exists in the gate insulating layer, the phenomenon may be made stronger by the existence nitrogen.

### BRIEF SUMMARY OF THE INVENTION

Object of the Invention

It is an object of the present invention to provide a method for manufacturing semiconductor devices that can restrain the decline of the long term reliability of the semiconductor device due to the lowering of the drive ability of p-type MOS FET based on generation of fixed charges at an interface between a gate insulating layer and a silicon substrate under a high temperature bias situation.

### SUMMARY OF THE INVENTION

The method for manufacturing semiconductor devices, according to the present invention, that include transistors for peripheral circuits to which input and output signal lines are connected and transistors for internal circuits that have lower operation voltage than that of the transistors for peripheral circuits consists of the steps of exposing a surface of a first region forming the transistors for peripheral circuits of a semiconductor substrate, forming a first gate oxide layer by oxidizing the exposed surface of the first region in an oxidizing atmospheric gas including hydrogen atoms, exposing a surface of a second region forming the transistors for internal circuits of the semiconductor substrate, and forming a second gate oxide layer by oxidizing the exposed surface of the second region in an oxidizing atmospheric gas without hydrogen atoms and subsequently by oxidizing the exposed surface in a nitrogen monoxide atmosphere.

### BRIEF DESCRIPTION OF THE DRAWINGS

The above-mentioned and other objects, features and advantages of this invention will become more apparent by reference to the following detailed description of the invention taken in conjunction with the accompanying drawings, wherein;

FIGS. 1A to 1C are cross-sectional views showing in processing sequence a method for manufacturing semiconductor devices of the first embodiment according to the present invention;

FIGS. 2A to 2B are cross-sectional views showing manufacturing processes following FIG. 1; and

FIGS. 3A to 3C are cross-sectional views showing in processing sequence a method for manufacturing semiconductor devices of the second embodiment according to the present invention.

### DETAILED DESCRIPTION OF THE INVENTION

Before explaining the embodiment of the present invention, the prehistory to the present invention will be simply described below.

As discussed above, the BT instability derives from the fact that holes generated in an inversion layer of a p-type MOS FET cause the electrochemistry reaction at an interface between an insulating layer and a silicon substrate. It is known that the electrochemistry reaction is an action in which hydrogen is dissociated from a dangling bond which is terminated with hydrogen.

As a result of experiments according to the applicants of the present application on the basis of these phenomena, it was found that the reaction was restrained based on the isotope effect by terminating the dangling bond with heavy hydrogen.

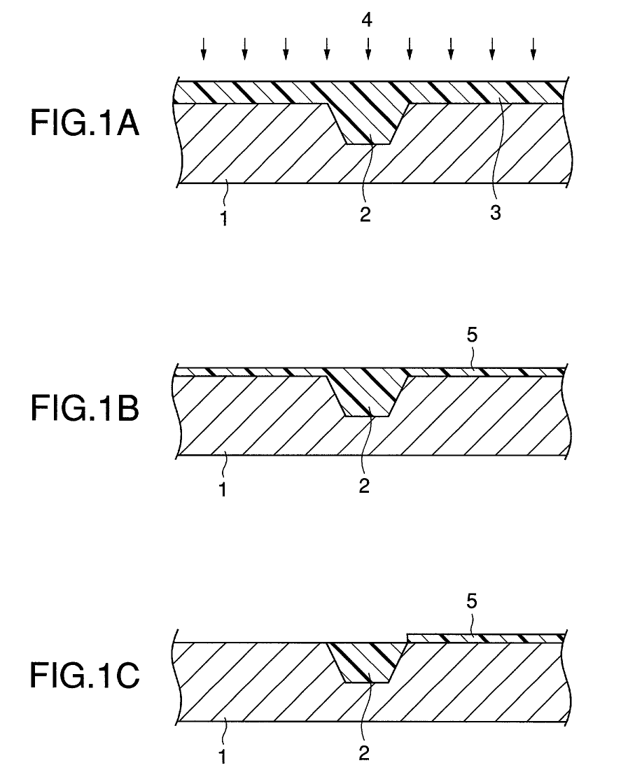

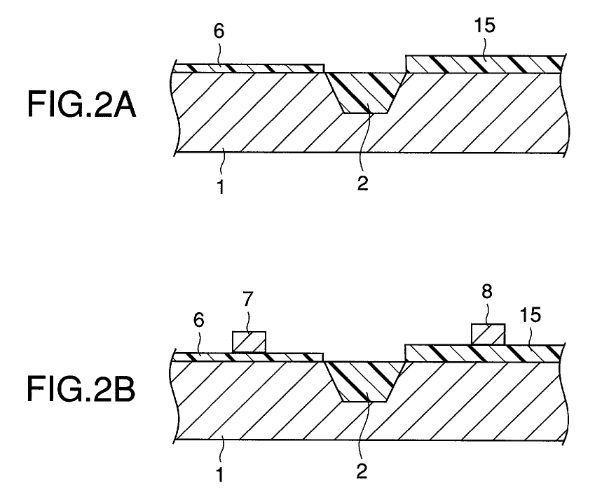

Next, the first embodiment of the present invention will be described with reference to cross-sectional views of the processes shown in FIG. 1 and FIG. 2. The cross-sectional views of the processes of the MOS FET for the peripheral circuit to which the input and output signal lines of the CMOS LSI are directly connected and the MOS FET for the internal circuit is shown at the same time. As the power supply voltage of the MOS FET for the peripheral circuit is generally set up at higher value than that of the MOS FET for the internal circuit, the insulating layer of the MOS FET for the peripheral circuit is made thick. In the embodiment of the present invention, although the manufacturing process of p-type MOS FET is shown as an example, n-type MOS FET can be fabricated as the same process.

First of all, a silicon oxide layer 3 with the layer thickness of 16 nm is formed on a semiconductor substrate 1 on which an element separating region 2 is determined by thermal oxidation of the semiconductor substrate 1, as shown in FIG. 1A.

Subsequently, arsenic 4 is ion implanted for the purpose of controlling a threshold voltage of the p-type MOS FET.

Next, after the silicon oxide layer 3 has been removed by wet etching, a gate insulating layer 5 with the layer thickness of 5.5 nm is formed by thermal oxidation of the semiconductor substrate 1, as shown in FIG. 1B. The atmospheric gas forming the gate insulating layer 5 may be a mixing atmospheric gas of hydrogen and oxygen, and the gate insulating layer 5 may be a silicon oxide layer including hydrogen.

Then, as shown in FIG. 1C, the gate insulating layer 5 existing on the region in which the MOS FET for the internal circuit is formed is selectively removed by photolithography.

Subsequently, as shown in FIG. 2A, in order to form a gate insulating layer 6 of the MOS FET for the internal circuit, the semiconductor substrate 1 is heated in an oxidizing atmospheric gas, followed by heating in a nitrogen monoxide atmosphere to introduce nitrogen into the silicon oxide layer.

As described above, the layer thickness of the gate insulating layer 6 for the internal circuit of the MOS FET for the internal circuit is controlled by adjusting the temperature and time to heat the semiconductor substrate 1 in the oxidizing atmosphere and the nitrogen monoxide atmosphere, and in the present embodiment, it may be 2.0 nm.

Further, the oxidizing atmospheric gas to form the gate insulating layer 6 for the internal circuit of the MOS FET for the internal circuit is an oxygen gas in which hydrogen atoms do not exist. Similarly, there are no molecules including hydrogen molecules and atoms in the nitrogen monoxide atmosphere. Consequently, this prevents occurrence of the dangling bond terminated with hydrogen at the interface between the gate insulating layer and the semiconductor substrate. The layer thickness of a gate insulating layer 15 for the peripheral circuit of the MOS FET for the peripheral circuit is made 6.0 nm due to the gate insulating layer forming process of the MOS FET for the internal circuit.

Subsequently, in order to form gate electrodes shown in FIG. 2B, processes of patterning using deposition of polycrystalline silicon and photolithography and further reactive ion etching are performed to form a gate electrode 7 for the internal circuit and a gate electrode 8 for the peripheral circuit on the MOS FET for the internal circuit and the MOS FET for the peripheral circuit, respectively.

Then, side walls of the gates, electrodes of a source and a drain, and a wiring layer are formed using the ordinary semiconductor manufacturing processes to manufacture a CMOS LSI composed of MOS FETs for the peripheral circuits and MOS FETs for internal circuits. As the manufacturing processes are well-known, the explanation of the process is omitted.

When the CMOS LSIs are manufactured according to the present embodiment, the layer thickness of the MOS FET for the peripheral circuit and the MOS FET for the internal circuit in the MOS FETs manufactured are different, and hydrogen exists in the gate insulating layer of the MOS FET for the peripheral circuit and, on the other hand, hydrogen does not exist in the gate insulating layer of the MOS FET for the internal circuit, which is different from MOS FETs made by conventional processes.

The power supply voltage of the MOS FET for the peripheral circuit is usually set up to the range of 2.5V and 3.3V in order to match with circuits external to the CMOS LSI. When the power supply voltage is set up in this range, a gate insulating layer with the layer thickness of from 5.0 nm to 8.0 nm based on the dielectric breakdown resistance properties such as TDDB (Time Dependent Dielectric Breakdown) properties. In this case, the electric fielf applied to the gate insulating layer is less than 5 MV/cm, so that there is no need to take the BT instability into account. Rather, the dielectric breakdown resistance properties should be emphasized, and for this purpose, the gate insulating layer including hydrogen is preferable as reported in M. Kimura et al., International Reliability Physics Symposium Proceedings, p. 190, 1997.

On the other hand, considering manufacturing processes of CMOS LSIs that are generally now in a development stage, the layer thickness of the gate insulating layer in internal circuits of the LSI according to the present embodiment is made 2.0 nm, and in order to satisfy the performance required to MOS FETs, the power supply voltage is generally set up to approximately 1.2V.

In this case, the electric field that should take the BT instability into account is applied to the gate insulating layer. In addition, a gate leak current due to the tunnel phenomenon may directly flow through the gate insulating layer that is made thin to this level, so that the dielectric breakdown resistance properties such as TDDB properties of the gate insulating layer shows excellent properties compared to the conventional gate insulating layer with the layer thickness of 3.0 nm or more.

Judging from this result, the gate insulating layer should be formed with making much account of the BT instability rather than the dielectric breakdown resistance properties, and the gate insulating layer is preferably made not to include hydrogen.

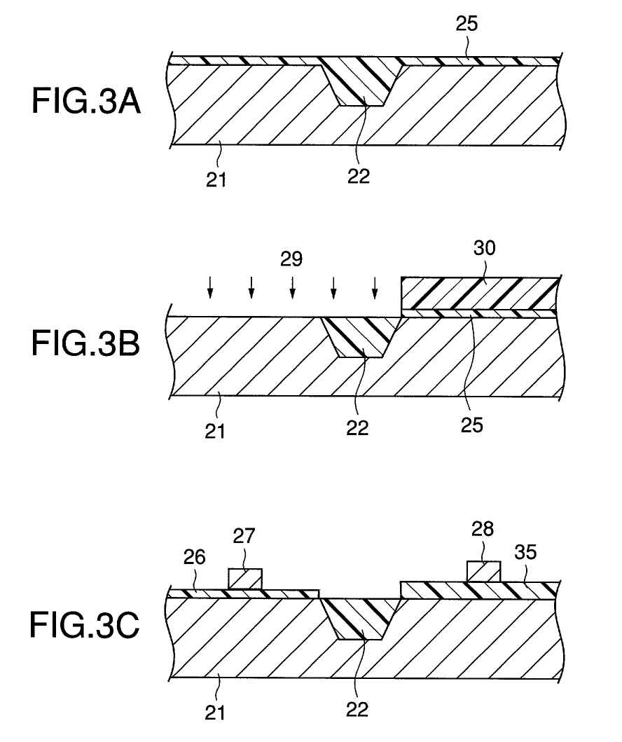

Then, the second embodiment according to the present invention will be described with reference to FIG. 3.

Firstly, a gate insulating layer 25 of the MOS FET for the peripheral circuit is formed in a similar manner to the first embodiment, as shown in FIG. 3A.

Subsequently, as shown in FIG. 3B, based on photolithography, the gate insulating layer 25 existing on the region in which the MOS FET for the internal circuit is formed is selectively removed by wet etching using a photoresist 30 as a mask, then, fluorine 29 is introduced into a silicon substrate 21 with ion implantation. The implantation rate of fluorine 29 may be in the range of 1× 10¹⁴ to 5×10¹⁴/cm².

After the photoresist 30 has been removed, according to the same processes as is used in the first embodiment, a gate insulating layer 26 for the internal circuit of the MOS FET for the internal circuit and a gate insulating layer 35 for the peripheral circuit are formed. If the implantation rate of fluorine 29 exists in the range described above, the layer thickness of the gate insulating layer 26 for the internal circuit would be free from the effect of fluorine.

In addition, if the silicon substrate is subjected to a thermal oxidation in an oxidizing atmosphere, oxidation species of the silicon substrate are oxygen molecules rather than water molecules when hydrogen is included. In this case, as the diffusion of oxygen molecules in the insulating layer is subjected to rate controlling, the layer forming speed of the insulating layer is less susceptible to the state of the silicon substrate. Therefore, the oxidizing atmosphere that does not include hydrogen can form the gate insulating layer with better controllability.

Further, if the gate insulating layer is formed in a gas atmosphere including hydrogen after fluorine 29 has been implanted, fluorine atoms diffuses outward in the form of hydrogen fluoride gas, causing the density of fluorine atoms at the interface between the insulating layer and the silicon substrate to be decreased. In order to restrain this effect, it is preferable to thermally oxidize the silicon substrate in the oxidizing atmosphere without hydrogen.

When fluorine is introduced into the silicon substrate in this way, the dangling bond at the interface between the gate insulating layer and the silicon substrate is terminated with fluorine. Therefore, even when the semiconductor substrate is exposed to an atmosphere including hydrogen in processes after the gate insulating layer is formed, hydrogen diffused to the gate insulating layer is inhibited to terminate the dangling bond, causing occurrence of the BT instability to be restrained.

After the gate insulating layer 26 for the internal circuit of the MOS FET for the internal circuit, a gate electrode 27 for the internal circuit of the MOS FET for the internal circuit and a gate electrode 28 for the peripheral circuit of the MOS FET for the peripheral circuit composed of polycrystalline silicon are formed by depositing polycrystalline silicon and according to the processes shown in the first embodiment, thereafter, CMOS LSIs are manufactured according to the usual processes.

As described above, when the method for manufacturing semiconductor devices according to the present invention is used, hydrogen is not included in the gate insulating layer of the MOS FET for the internal circuit by oxidizing the gate insulating layer of the MOS FET for the internal circuit in the gas atmosphere without hydrogen, causing the deterioration due to the BT instability to be restrained.

In addition, by introducing fluorine before formation of the gate insulating layer of the MOS FET for the internal circuit, the deterioration due to the BT instability may be restrained.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A method for manufacturing semiconductor devices having transistors for peripheral circuits to which input and output signal lines are connected and transistors for internal circuits that have lower operation voltage than that of said transistors for peripheral circuits, said method for manufacturing semiconductor devices comprising the steps of:
exposing a surface of a first region forming said transistors for peripheral circuits of a semiconductor substrate; forming a first gate oxide layer by oxidizing said exposed surface of said first region in an oxidizing atmospheric gas including hydrogen atoms; exposing a surface of a second region forming said transistors for internal circuits of said semiconductor substrate; and forming a second gate oxide layer by oxidizing said exposed surface of said second region in an oxidizing atmospheric gas without hydrogen atoms and subsequently by oxidizing said exposed surface in a nitrogen monoxide atmosphere.

2. The method for manufacturing semiconductor devices according to claim 1, wherein a layer thickness of said gate oxide layer of said transistors for internal circuits is formed less than 2.8 nm, and a layer thickness of said gate oxide layer of said transistors for peripheral circuits is formed more than 2.8 nm.

3. The method for manufacturing semiconductor devices according to claim 1, further comprising a step of introducing fluorine into said exposed second region between said step of exposing said surface of said second region and said step of forming said second gate oxide layer.

4. The method for manufacturing semiconductor devices according to claim 3, wherein, in said step of introducing fluorine into said exposed second region, said fluorine is ion implanted to an implantation rate of a range from 1× 10¹⁴ to 5×10¹⁴/cm².
